(19) United States
(12) Patent Application Publication
(10) Pub. No.: US 2008/0198519 A1
(43) Pub. Date: Aug. 21, 2008

(54) ELECTROSTATIC DISCHARGE PROTECTION ELEMENT HAVING AN IMPROVED AREA EFFICIENCY

(76) Inventor: Dong Ju LIM, Gyeonggi-do (KR)

Correspondence Address: LADAS & PARRY LLP, 224 SOUTH MICHIGAN AVENUE, SUITE 1600, CHICAGO, IL, 60604, US

(21) Appl. No.: 12/031,235

(22) Filed: Feb. 14, 2008

(30) Foreign Application Priority Data
Feb. 15, 2007 (KR) 10-2007-0016256

(51) Int. Cl. H02H 9/00; H01L 27/06

(52) U.S. Cl. 361/56; 257/360; 257/E27.016

(57) ABSTRACT

An electrostatic discharge protection element is disclosed for protecting an internal circuit from electrostatic current. The electrostatic discharge protection element forms an embedded LVTSCR by adding a prescribed impurity region within an N-well region having a P-type diode formed therein. A P-well region having a GGNMOS transistor is also formed in the electrostatic discharge protection element. The embedded LVTSCR improves area efficiency, reduces a resistance, and lowers an operational voltage by reducing the distance between the P-type diode and the LVTSCR to allow high-speed operatation.

### CROSS-REFERENCE TO RELATED APPLICATIONS

The present application claims priority to Korean patent application number 10-2007-0016256 filed on Feb. 15, 2007, which is incorporated herein by reference in its entirety.

### BACKGROUND OF THE INVENTION

The present invention relates generally to a semiconductor memory device, and more particularly to an electrostatic discharge protection element that protects an internal circuit from an electrostatic current.

Generally, a semiconductor memory device has an electrostatic discharge protection element provided between an input/output pad and the internal circuit. The electrostatic discharge protection element serves to prevent damage to the internal circuit resulting from electrostatic current flowing in from a charged body or machine to the inside of the semiconductor memory device, or the electrostatic current flowing out through the machine after being charged within the semiconductor memory device.

The electrostatic discharge protection element is typically implemented using a diode, a metal oxide semiconductor (MOS) transistor, a silicon-controlled rectifier (SCR) that lowers a trigger voltage, and the like.

The diode is suitable for high integration and high-speed applications since an electrostatic current capable of being carried per unit area is high and a bonding capacitance is small. However, there is a limitation in using the diode independently since a reverse turn-on voltage is high and electrostatic discharge protection performance is low in a reverse direction condition.

The SCR discharges a high amount of current per unit area, though it has a problem where a gate oxide film of the semiconductor internal element can be damaged before the electrostatic discharge protection element operates when the electrostatic current is generated due to a high trigger voltage.

Referring to FIG. 1, an electrostatic discharge protection element according to the prior art has a P-type diode 10 and a GGNMOS (Gate Ground NMOS) transistor 20 having an input/output pad (PAD) disposed between the P-type diode 10 and the GGNMOS transistor 20. The electrostatic discharge protection element according to the prior art additionally has a power clamp 30 disposed between the voltage lines VCC and VSS so that a forward characteristic of the diode can be provided in all discharge paths and the electrostatic discharge protection performance can be improved. Herein, the power clamp 30 can be implemented as a diode, a MOS transistor, and a SCR.

However, the electrostatic discharge protection element according to the prior art mentioned above increases the area of the element due to the power clamp 30, which is disadvantageous.

Further, the power clamp 30 must be disposed adjacent to the diode 10 as close as possible since a resistance component between the power clamp 30 and the diode 10 must be reduced in order to induce the forward characteristic of the diode 10. However, it is difficult to dispose the power clamp 30, which has a large area, adjacent to the diode 10 when the size of the input/output pad and a distance between the input/output pads is decreased.

### SUMMARY OF THE INVENTION

Therefore, the present invention provides an electrostatic discharge protection element that improves area efficiency by embedding a power clamp within a diode region and GGNMOS transistor region.

The present invention also lowers the trigger voltage of the power clamp and thereby enhances the electrostatic discharge efficiency by reducing a distance between the diode and the power clamp and therefore reducing a resistance component present between the diode and the power clamp.

The electrostatic discharge protection element according to an embodiment of the present invention comprises a semiconductor substrate; an N-well region formed in a prescribed region of the substrate; a P-well region formed adjacent to the N-well region; a diode region formed within the N-well region; a P-type impurity region formed surrounding the diode region at a prescribed distance from a side surface of the diode region; a MOS transistor region formed across the N-well region and the P-well region; and a guard ring formed at a prescribed distance from a one side surface of the MOS transistor.

Preferably, the diode region comprises a P-type impurity region formed to couple with an input/output pad in a center portion of the diode region; and an N-type impurity region formed to couple with a power supply voltage terminal at a prescribed distance from both side surfaces of the P-type impurity region.

Preferably, the P-type impurity region is couple to a power supply voltage terminal.

Preferably, the MOS transistor region comprises a first N-type impurity region formed across the N-well region and the P-well region; a plurality of second N-type impurity regions formed within the P-well region at a prescribed distance from the first N-type impurity region; and a plurality of gates formed to intersect on a top portion of the first and second N-type impurity regions.

Preferably, the second N-type impurity regions and the gates are coupled to a ground voltage terminal.

Preferably, the guard ring region is a P-type impurity and is coupled to a ground voltage terminal.

Preferably, the electrostatic discharge protection element according to another embodiment of the present invention further comprises an assistance trigger unit that outputs a detection voltage in correspondence with the beginning of electrostaticity generation, and the detection voltage is applied to the first N-type impurity region.

Preferably, the assistance trigger unit is a RC circuit coupled between the power supply voltage terminal and the ground voltage terminal, and the RC circuit comprises a resistor and a capacitor coupled in series.

### BRIEF DESCRIPTION OF THE DRAWINGS

FIG. 1 is a block diagram illustrating an electrostatic discharge protection circuit according to the prior art.

FIG. 2 is a layout diagram illustrating a structure of the electrostatic discharge protection element according to an embodiment of the present invention.

FIG. 3 is a cross-sectional view of the electrostatic discharge protection element of FIG. 2 along a line A1-A2.

FIG. 4a is a diagram showing an electrostatic discharge path in which the electrostatic current flowing in to an input/output pad is discharged to a ground voltage terminal.

FIG. 4b is a diagram showing an electrostatic discharge path in which the electrostatic current flowing in to an input/output pad is discharged to a power supply voltage terminal.

FIG. 5 is a cross-sectional diagram showing a structure of the electrostatic discharge protection element according to another embodiment of the present invention.

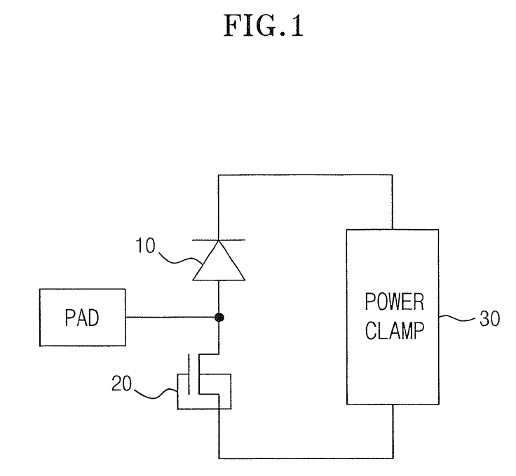

### DESCRIPTION OF SPECIFIC EMBODIMENTS

Hereinafter, embodiments of the present invention will be described in detail with reference to the accompanying drawings.

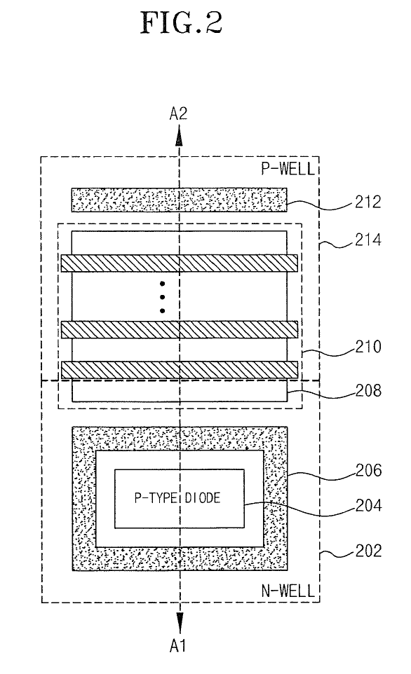

The present invention is related to an electrostatic discharge protection element that reduces a distance between a diode and a power clamp and improves area efficiency by embedding the power clamp within the diode and the GGNMOS transistor. An embodiment of the present invention will be described referring to FIG. 2.

Referring to FIG. 2, the electrostatic discharge protection element according to an embodiment of the present invention includes a P-type diode 204 formed within an N-well region 202 and a GGNMOS transistor 210 formed across the N-well region 202 and a P-well region 214.

A P-type impurity region 206 is formed within the N-well region 202 by a prescribed distance surrounding the P-type diode 204 to serve as an anode of a low voltage silicon-controlled rectifier (LVTSCR). Additionally, a P-type guard ring 212 is formed within the P-well region 214 at a prescribed distance from the GGNMOS transistor 210 to be responsible for pick up and at the same time serve as a cathode of the LVTSCR.

Herein, an N-type impurity region 208 is formed to intersect with the N-well region 202 and the P-well region 214 and is responsible for reducing a breakdown voltage at a middle bonding region of the LVTSCR.

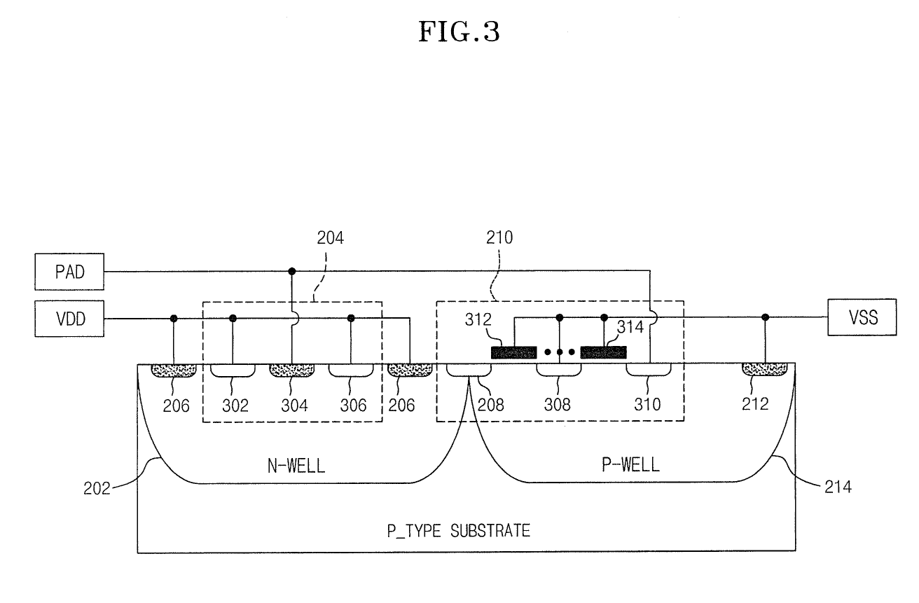

Referring to FIG. 3, a cross-sectional view of the electrostatic discharge protection element according to an embodiment of the present invention is shown. The P-type diode 204 has a P-type impurity region 304 formed to couple to an input/output pad PAD in a center portion of the P-type diode 204 and N-type impurity regions 302, 306 formed to couple to a power supply voltage terminal VDD at a prescribed distance from a side surface of the P-type impurity region 304.

The GGNMOS transistor 210 has an N-type impurity region 208 formed to intersect the N-well region 202 and the P-well region 214, an N-type impurity region 308 formed to couple to a ground voltage terminal VSS at a prescribed distance from a side surface of the N-type impurity region 208, and an N-type impurity region 310 formed to couple to the input/output pad PAD at a prescribed distance from a side surface of the N-type impurity region 308. N-type gates 312, 314 are formed to couple the ground voltage terminal above and between N-type impurity regions 208 and 308, and 308 and 310.

Herein, the GGNMOS transistor 210 can include the N-type impurity region 208 coupled to the ground voltage terminal VSS, the N-type impurity region 310 coupled to the input/output pad PAD, and a plurality of the N-type gates 314 formed on the top portions to couple to the ground voltage terminal VSS.

The P-type impurity region 206 is formed at a prescribed distance to surround the P-type diode 204 within the N-well region 202 and is coupled to the power supply voltage terminal VDD to serve as an anode of the LVTSCR. The N-type impurity region 208 is formed to intersect the N-well region 202 and the P-well region 214 and is responsible for reducing the breakdown voltage of the LVTSCR. Finally, the P-type guard ring 212 is formed at a prescribed distance from a side surface of the GGNMOS transistor 210 within the P-well region 214 and is coupled to the ground voltage terminal VSS to serve as a cathode of the LVTSCR.

As in the previous embodiment of the present invention, it is possible to embed the LVTSCR by additionally forming the P-type impurity region 206 and the N-type impurity region 208 within the N-well region 202 having the P-type diode 204 formed therein and the P-well region 214 having the GGNMOS transistor 210 formed therein. Embedding the LVTSCR results in improved area efficiency.

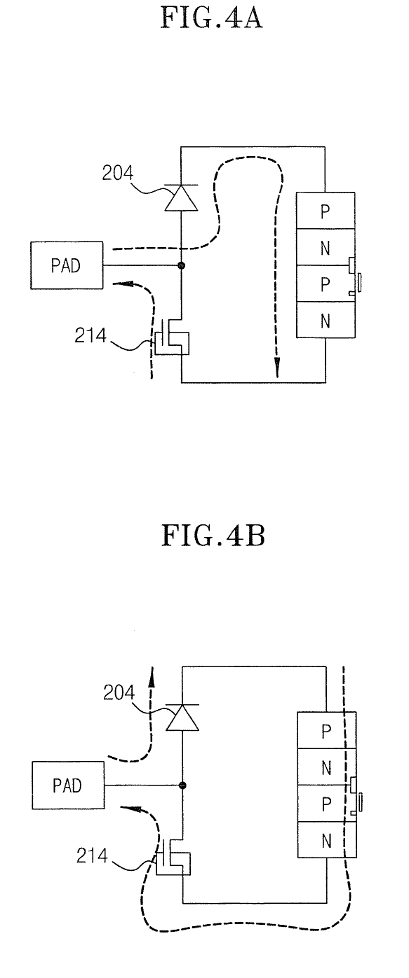

Referring to FIG. 4a, a path of discharging the electrostatic current flowing in from the input/output pad PAD to the ground voltage terminal VSS is shown. Positive electrostatic charge flows in through the P-type diode 204 to the power supply voltage terminal VDD and is discharged through the P-type impurity region 206 corresponding to the anode of the LVTSCR, N-well 202, P-well 214 and the P-type guard ring 212 corresponding to a cathode of the LVTSCR to the ground voltage terminal VSS. Negative electrostatic charge is discharged from the ground voltage terminal VSS through the GGNMOS transistor 210 to the input/output pad PAD.

Referring to FIG. 4b, a path of discharging the electrostatic current flowing in from the input/output pad PAD to the power supply voltage terminal VDD is shown. Positive electrostatic charge is discharged through the P-type diode 204 to the power supply voltage terminal VDD. Negative electrostatic charge flows in from the power supply voltage terminal VDD through the embedded LVTSCR to the ground voltage terminal VSS and discharged through the GGNMOS transistor 210 to the input/output pad PAD.

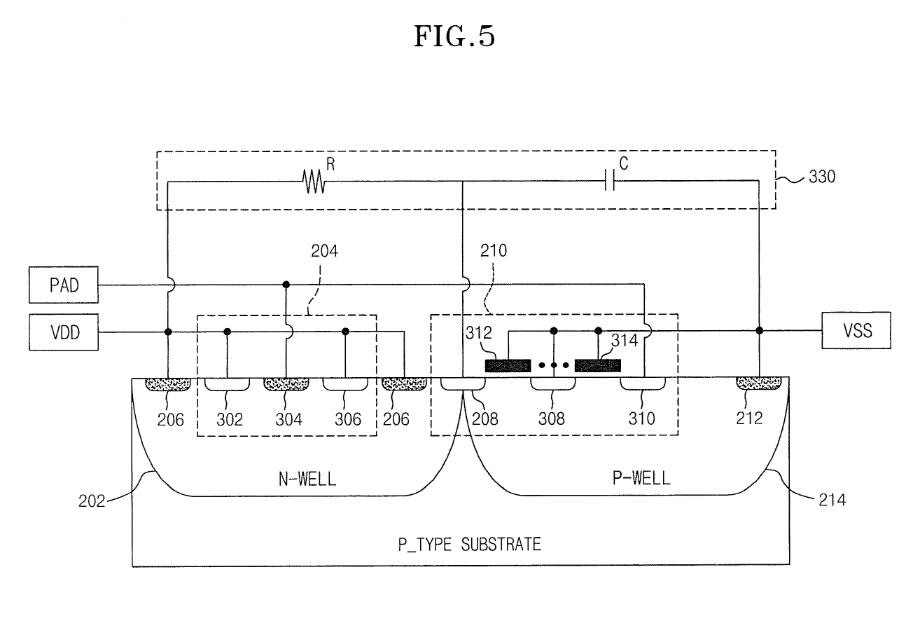

Referring to FIG. 5, the electrostatic discharge protection element according to another embodiment of the present invention has the same cross-sectional structure as the previously discussed embodiment. However, the embodiment of FIG. 5 further includes a trigger assistance unit 330 that detects a voltage based on the electrostatic current and applies it to the N-type impurity region 208 to lower the breakdown voltage of the embedded LVTSCR.

The trigger assistance unit 330 can be implemented using a resistor R and a capacitor C coupled in series between the power supply voltage terminal VDD and the ground voltage terminal VSS. A withstanding voltage between the N-type impurity region 208 and the P-well 214 can be reduced by detecting a voltage drop occurring between the resistor R and the capacitor C in correspondence with an alternative component of the electrostatic current and applying it to the N-type impurity region 208 which was in a floating state in the previous embodiment. This results in lowering the trigger voltage as compared with the LVTSCR of the previously discussed embodiment.

As described above, the present invention improves area efficiency of the electrostatic discharge protection element by embedding the LVTSCR, which is a power clamp element, within the diode-forming region and the GGNMOS transistor-forming region.

Further, according to the present invention, it is possible to prevent a discharge efficiency of the power clamp from lowering due to a parasitic resistance by reducing the distance between the diode and the power clamp.

Those skilled in the art will appreciate that the specific embodiments disclosed in the foregoing description may be readily utilized as a basis for modifying or designing other embodiments for carrying out the same purposes of the present invention. Those skilled in the art will also appreciate that such equivalent embodiments do not depart from the spirit and scope of the invention as set forth in the appended claims.

What is claimed is:

1. An electrostatic discharge protection element, comprising:
a semiconductor substrate;
an N-well region formed in a prescribed region of the substrate;
a P-well region formed adjacent to the N-well region;
a diode region formed within the N-well region having a plurality of edges;
a P-type impurity region formed to surround the diode region at a prescribed distance from the plurality of edges of the diode region;
a metal oxide semiconductor (MOS) transistor region formed across a portion of the N-well region and a portion of the P-well region; and
a guard ring formed at a prescribed distance from a side surface of the MOS transistor.

2. The electrostatic discharge protection element as set forth in claim 1, wherein the diode region comprises:
a P-type impurity region formed in a center portion of the diode region to couple to an input/output pad; and
a N-type impurity region formed at a prescribed distance from both sides of the P-type impurity region to couple to a power supply voltage terminal.

3. The electrostatic discharge protection element as set forth in claim 1, wherein the P-type impurity region is coupled to a power supply voltage terminal.

4. The electrostatic discharge protection element as set forth in claim 1, wherein the MOS transistor region comprises:
a first N-type impurity region formed across the N-well region and the P-well region intersecting the N-well region and the P-well region;
a plurality of second N-type impurity regions formed within the P-well region at a prescribed distance from the first N-type impurity region; and
a plurality of gates formed on a upper surface of the first and second N-type impurity regions to intersect the first and second N-type impurity regions.

5. The electrostatic discharge protection element as set forth in claim 4, wherein the plurality of second N-type impurity regions is coupled to a ground voltage terminal.

6. The electrostatic discharge protection element as set forth in claim 4, wherein the plurality of gates is coupled to a ground voltage terminal.

7. The electrostatic discharge protection element as set forth in claim 4, wherein the guard ring region is a P-type impurity.

8. The electrostatic discharge protection element as set forth in claim 4, wherein the guard ring region is coupled with a ground voltage terminal.

9. The electrostatic discharge protection element as set forth in claim 1, further comprising an assistance trigger unit that outputs a detection voltage in correspondence with a beginning of electrostatic generation.

10. The electrostatic discharge protection element as set forth in claim 4, further comprising an assistance trigger unit that outputs a detection voltage in correspondence with a beginning of electrostatic generation, wherein the detection voltage is applied to the first N-type impurity region.

11. The electrostatic discharge protection element as set forth in claim 9, wherein the MOS transistor region comprises:
a first N-type impurity region formed across the N-well region and the P-well region intersecting the N-well region and the P-well region;
a plurality of second N-type impurity regions formed within the P-well region at a prescribed distance from the first N-type impurity region; and
a plurality of gates formed on a upper surface of the first and second N-type impurity regions to intersect the first and second N-type impurity regions,
wherein the detection voltage is applied to the first N-type impurity region.

12. The electrostatic discharge protection element as set forth in claim 9, wherein the assistance trigger unit is a RC circuit coupled between a power supply voltage terminal and a ground voltage terminal.

13. The electrostatic discharge protection element as set forth in claim 12, wherein the RC circuit comprises a resistor and a capacitor coupled in series.
